(19) United States
(12) Patent Application Publication
(10) Pub. No.: US 2026/0319169 A1
(43) Pub. Date: Oct. 15, 2026

(54) SEMICONDUCTOR PACKAGE

(71) Applicant: Samsung Electronics Co., Ltd., Suwon-si (KR)

(72) Inventor: Hyeonjeong Hwang, Suwon-si (KR)

(21) Appl. No.: 19/467,365

(22) Filed: Feb. 2, 2026

(30) Foreign Application Priority Data
Feb. 10, 2025 (KR) 10-2025-0016957

(51) Int. Cl. G02B 6/12; G02B 6/122; H10B 80/00; H10D 80/30; H10W 20/20; H10W 70/63; H10W 90/00; H10W 70/05; H10W 80/00

(52) U.S. Cl. CPC G02B 6/12004; G02B 6/12002; G02B 6/122; H10B 80/00; H10D 80/30; H10W 20/222; H10W 70/635; H10W 90/7295; H10W 90/794; G02B 2006/12085; G02B 2006/12111; G02B 2006/12176; H10W 70/095; H10W 80/312; H10W 80/327

(57) ABSTRACT

A semiconductor package includes a body having an upper surface and a lower surface and including a groove extending downward from the upper surface of the body in a vertical direction, an oxide layer on the body, including therein a waveguide and an optical component connected to the waveguide, and not overlapping the groove of the body in the vertical direction, an upper wiring layer on the oxide layer and including an upper wiring pattern and an upper wiring insulating layer, a through-electrode connected to the upper wiring pattern and passing through the body and the oxide layer in the vertical direction, a bonding pad, a bonding insulating layer, an electronic integrated circuit chip on the bonding pad and the bonding insulating layer, and an optical fiber mounted in the groove via a protrusion and in contact with the upper wiring layer in a lateral direction.

### CROSS-REFERENCE TO RELATED APPLICATION

This application claims priority under 35 U.S.C. §119 to Korean Patent Application No. 10-2025-0016957, filed on Feb. 10, 2025, in the Korean Intellectual Property Office, the entirety of which is incorporated by reference herein.

### BACKGROUND

Electronic equipment is becoming smaller and lighter according to the rapid development of electronic industries and users' demands. As electronic equipment becomes smaller and lighter, semiconductor packages used therein are also becoming smaller and lighter, and the high degree of integration of semiconductor devices is required.

Accordingly, semiconductor packages are being developed, in which various integrated circuits, such as memory chips and logic chips, are mounted on package substrates to provide multiple functions. In particular, in a recent environment in which data traffic is increasing in data centers and communication infrastructure, research is being conducted on semiconductor packages including photonic integrated circuits.

### SUMMARY

Some aspects of the present disclosure provide semiconductor packages having improved signal transmission reliability of optical fiber and enhanced heat dissipation characteristics. Other advantages and aspects of the present disclosure will be clearly understood by those skilled in the art from the following description.

According to some implementations of the present disclosure, there is provided a semiconductor package including a body having an upper surface and a lower surface and including a groove extending downward from the upper surface of the body in a vertical direction, an oxide layer disposed on the body, including therein a waveguide and an optical component connected to the waveguide, and not overlapping the groove of the body in the vertical direction, an upper wiring layer disposed on the oxide layer and including an upper wiring pattern and an upper wiring insulating layer surrounding the upper wiring pattern, a through-electrode connected to the upper wiring pattern and passing through the body and the oxide layer in the vertical direction, a bonding pad on the upper wiring layer, a bonding insulating layer surrounding a side surface of the bonding pad, an electronic integrated circuit (EIC) chip on the bonding pad and the bonding insulating layer, and an optical fiber mounted in the groove via a protrusion and in contact with the upper wiring layer in a lateral direction.

According to some implementations of the present disclosure, there is provided a semiconductor package including an interposer substrate, an EIC chip on the interposer substrate, a first semiconductor chip disposed on the interposer substrate and spaced apart from the EIC chip in a horizontal direction, a second semiconductor chip disposed on the interposer substrate and located between the first semiconductor chip and the EIC chip, and an optical fiber having a protrusion and in contact with the interposer substrate in the horizontal direction, wherein the interposer substrate includes a body having an upper surface and a lower surface and including a groove extending downward from the upper surface of the body in a vertical direction, an oxide layer disposed on the body, including therein a waveguide and an optical component connected to the waveguide, and not overlapping the groove of the body in the vertical direction, an upper wiring layer disposed on the oxide layer and including an upper wiring pattern and an upper wiring insulating layer surrounding the upper wiring pattern, a bonding pad on the upper wiring insulating layer, a bonding insulating layer surrounding a side surface of the bonding pad, and a through-electrode connected to the upper wiring pattern and passing through the body and the oxide layer in the vertical direction, wherein an EIC chip bonding pad and an EIC chip bonding insulating layer surrounding a side surface of the EIC chip bonding pad are disposed on a lower surface of the EIC chip, a first semiconductor chip bonding pad and a first semiconductor chip bonding insulating layer are disposed on a lower surface of the first semiconductor chip, a second semiconductor chip bonding pad and a second semiconductor chip bonding insulating layer are disposed on a lower surface of the second semiconductor chip, the EIC chip bonding pad, the first semiconductor chip bonding pad, and the second semiconductor chip bonding pad are each in contact with the bonding pad in the vertical direction, and the bonding insulating layer is at least partially exposed upward in the vertical direction at the EIC chip bonding insulating layer, the first semiconductor chip bonding insulating layer, and the second semiconductor chip bonding insulating layer.

According to some implementations of the present disclosure, there is provided a semiconductor package including an interposer substrate including a body having an upper surface and a lower surface and including a groove extending downward from the upper surface of the body in a vertical direction, an oxide layer disposed on the body, including therein a waveguide and an optical component connected to the waveguide, and not overlapping the groove of the body in the vertical direction, an upper wiring layer disposed on the oxide layer and including an upper wiring pattern and an upper wiring insulating layer surrounding the upper wiring pattern, and a through-electrode connected to the upper wiring pattern and passing through the body and the oxide layer in the vertical direction, an EIC chip disposed on the interposer substrate and including, on a lower surface thereof, an EIC chip bonding pad and an EIC chip bonding insulating layer, a first semiconductor chip disposed on the interposer substrate, spaced apart from the EIC chip in a horizontal direction, and including, on a lower surface, a first semiconductor chip bonding pad and a first semiconductor chip bonding insulating layer, a second semiconductor chip disposed on the interposer substrate, located between the first semiconductor chip and the EIC chip, and including, on a lower surface thereof, a second semiconductor chip bonding pad and a second semiconductor chip bonding insulating layer, and an optical fiber having a protrusion and in contact with the interposer substrate in the horizontal direction, wherein the EIC chip bonding pad, the first semiconductor chip bonding pad, and the second semiconductor chip bonding pad are each in contact with a bonding pad in the vertical direction, a bonding insulating layer is at least partially exposed upward in the vertical direction at the EIC chip bonding insulating layer, the first semiconductor chip bonding insulating layer, and the second semiconductor chip bonding insulating layer, the groove is located in a first region of the body, the oxide layer includes a first oxide layer and a second oxide layer, the waveguide and the optical component are disposed on an upper surface of the first oxide layer, the groove does not overlap the upper wiring pattern and the bonding pad in the vertical direction, and a depth of the groove is in a range of about 20 nm to about 40 nm.

### BRIEF DESCRIPTION OF THE DRAWINGS

FIG. 1 is a plan view schematically showing an example of a semiconductor package;

FIG. 2 is a cross-sectional view of the semiconductor package, taken along line A1-A1' of FIG. 1;

FIG. 3 is a cross-sectional view schematically showing an example of the semiconductor package, taken along line B1-B1' of FIG. 1;

FIG. 4 is a cross-sectional view schematically showing an example of the semiconductor package, taken along line B1-B1' of FIG. 1;

FIG. 5 is a cross-sectional view schematically showing an example of the semiconductor package, taken along line B1-B1' of FIG. 1;

FIG. 6 is a schematic view showing an example of an upper surface of a body of the semiconductor package of FIG. 2;

FIG. 7 is a cross-sectional view of the body, taken along line C1-C1' of FIG. 6; and

FIGS. 8 to 18 are cross-sectional views illustrating an example of a method of manufacturing the semiconductor package of FIGS. 1 and 2.

### DETAILED DESCRIPTION

In the following description, the same reference numerals are given to the same elements in the drawings, and repeated descriptions thereof are omitted.

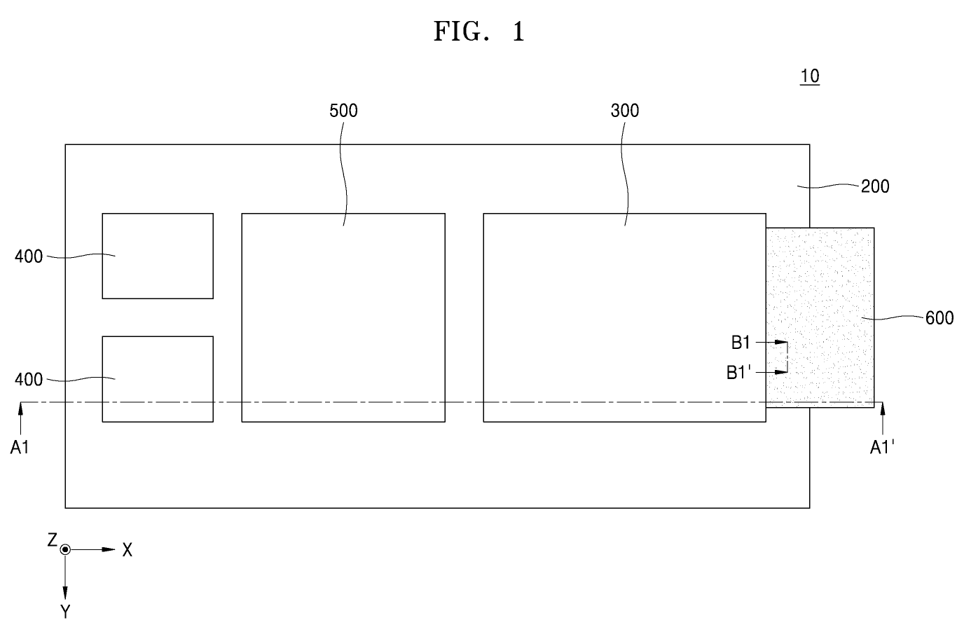

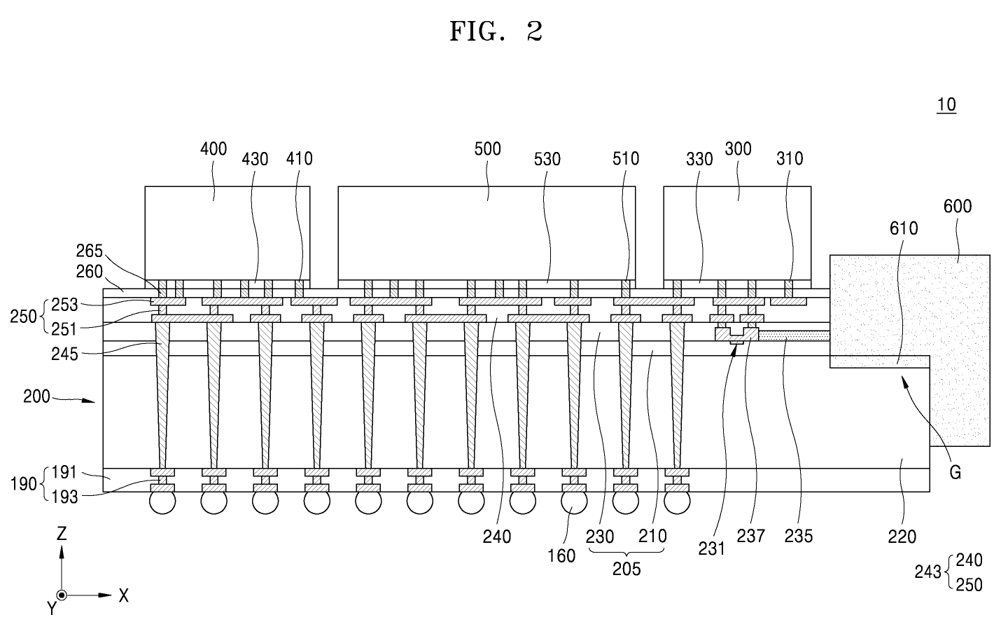

FIG. 1 is a plan view schematically showing an example of a semiconductor package 10. FIG. 2 is a cross-sectional view of the semiconductor package 10 taken along line A1-A1' of FIG. 1.

Referring to FIGS. 1 and 2, the semiconductor package 10 may include an interposer substrate 200, an optical fiber 600, an electronic integrated circuit (EIC) chip 300, a first semiconductor chip 400, and a second semiconductor chip 500. In some implementations, the semiconductor package 10 may be or include a semiconductor package that communicates with an external device via optical signals. For example, the semiconductor package 10 may be or include a semiconductor package having a silicon photonics engine.

The interposer substrate 200 may include a substrate formed based on silicon and electrically connect the EIC 300, the first semiconductor chip 400, and the second semiconductor chip 500 mounted on the interposer substrate 200 to each other. The interposer substrate 200 may function as a connection path electrically connecting the EIC 300, the first semiconductor chip 400, and the second semiconductor chip 500 to each other. In some implementations, when the EIC 300, the first semiconductor chip 400, and the second semiconductor chip 500 include different types of chips, the EIC 300, the first semiconductor chip 400, and the second semiconductor chip 500 may exchange electrical signals with each other via the interposer substrate 200.

The interposer substrate 200 may include a body 220, an oxide layer 205, a through-electrode 245, an upper wiring layer 243, and a lower wiring layer 190. The body 220 may include an upper surface and a lower surface. The body 220 may include silicon, for example, crystalline silicon, polycrystalline silicon, or amorphous silicon. Also, the body 220 may include semiconductor elements, such as germanium (Ge), or compound semiconductors, such as silicon carbide (SiC), gallium arsenide (GaAs), indium arsenide (InAs), and indium phosphide (InP). Also, the body 220 may have a silicon on insulator (SOI) structure. For example, the body 220 may include a buried oxide (BOX) layer.

In the following drawings, an X-axis direction and a Y-axis direction may represent directions parallel to the surface of the body 220, and it may be understood that the X-axis direction and the Y-axis direction are perpendicular to each other. A Z-axis direction may represent a direction perpendicular to the upper or lower surface of the body 220, that is, a direction perpendicular to the X-Y plane. Also, in the following drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

A groove G extending downward in a vertical direction Z from the upper surface of the body 220 may be located in the upper surface of the body 220. The groove G may include a groove in which the optical fiber 600 is mounted, which is described below. The cross-section of the groove G in the X-Z plane may be quadrangular, and the cross-section of the groove G in the Y-Z plane may have a shape of which the horizontal width decreases with decreasing vertical level. That is, the groove G may extend downward from the upper surface of the body 220 in the vertical direction Z, and the groove G may extend in the upper surface of the body 220 in a first horizontal direction X. A plurality of grooves G may be formed in the upper surface of the body 220, and the plurality of grooves G may be spaced apart from each other in a second horizontal direction Y. Each of the grooves G may extend in the first horizontal direction X.

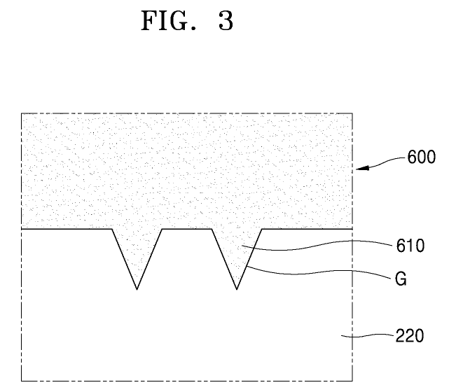

The groove G of the body 220 is described in detail below with reference to FIGS. 3 to 7.

The oxide layer 205 may be disposed on the upper surface of the body 220. In some implementations, the oxide layer 205 may include a plurality of layers. In FIG. 2, for convenience of illustration, the oxide layer 205 is shown as two layers, such as first and second oxide layers 210 and 230, but the oxide layer 205 may include three or more layers. Also, the oxide layer 205 may include a single layer.

In some implementations, the footprint of the oxide layer 205 may be smaller than the footprint of the body 220. The oxide layer 205 may not overlap the groove G of the body 220 in the vertical direction Z. The groove G in the upper surface of the body 220 may be formed in any one of regions of the upper surface of the body 220, which are exposed through the oxide layer 205.

In some implementations, the oxide layer 205 may include at least one of a silicon dioxide (SiO₂) layer, a silicon oxide layer, a high-temperature oxide layer, a low-temperature oxide layer, a plasma-enhanced oxide layer, a chemical vapor deposition oxide layer, a thermal oxide layer, a silicon-rich oxide layer, an impurity-doped oxide layer (e.g., a phosphosilicate glass (PSG) layer and a borophosphosilicate glass (BPSG) layer), a hydrogenated silicon oxide layer, or a BOX layer.

A photonic integrated circuit (PIC) 231 may be located inside the oxide layer 205. The PIC 231 may include a waveguide 235 and an optical component 237.

The waveguide 235 may be provided inside the second oxide layer 230. The waveguide 235 may include a patterned silicon layer and extend in the first horizontal direction X. However, the waveguide configuration is not limited thereto, and the waveguide 235 may be designed in various forms if necessary. In some implementations, the waveguide 235 may include at least one of silicon and silicon nitride. In some implementations, the waveguide 235 may be a silicon waveguide including silicon. The waveguide 235 may be connected to the optical component 237.

The optical component 237 may be provided inside the second oxide layer 230. The optical component 237 may convert electrical signals into optical signals and convert optical signals into electrical signals. In some implementations, the optical component 237 may include a photodetector, a photodiode, and/or a modulator.

While an optical signal is input to the PIC 231, the photodetector may detect the optical signal input to the PIC 231. The optical component 237 may detect an optical signal input via the photodetector and may convert the detected optical signal into an electrical signal.

While the PIC 231 outputs the optical signal, the EIC 300 may transmit the electrical signal to the modulator. The modulator may convert the electrical signal into an optical signal by inputting a signal corresponding to the received electrical signal to the light emitted from the photodiode.

In some implementations, components included in a PIC may be located inside the oxide layer 205. For example, in addition to the waveguide 235 and the optical component 237, various other components that constitute the PIC may be arranged inside the oxide layer 205.

The through-electrode 245 may pass through the oxide layer 205 and the body 220 in the vertical direction Z. The through-electrode 245 may extend in the vertical direction Z from the upper surface of the oxide layer 205 toward the lower surface of the body 220 and may be electrically connected to a lower wiring pattern 193 provided in a lower wiring layer 190. In some implementations, the through-electrode 245 may have a tapered shape of which the horizontal width decreases or increases with an increasing vertical level. The through-electrode 245 may have at least partially a pillar shape. The through-electrode 245 may include a through-silicon via (TSV).

The through-electrode 245 may not overlap the groove G in the vertical direction Z. The through-electrode 245 may not overlap the PIC 231 in the vertical direction Z.

The upper wiring layer 243 may be disposed on the oxide layer 205. The footprint of the upper wiring layer 243 may be substantially the same as the footprint of the oxide layer 205. The upper surface of the oxide layer 205 may not be exposed upward in the vertical direction Z by the upper wiring layer 243. That is, the upper wiring layer 243 may cover the upper surface of the oxide layer 205.

The upper wiring layer 243 may include an upper wiring pattern 250 and an upper wiring insulating layer 240. The upper wiring pattern 250 may electrically connect the EIC 300, the first semiconductor chip 400, and the second semiconductor chip 500 to each other, or may electrically connect the EIC 300 to the through-electrode 245, the first semiconductor chip 400 to the through-electrode 245, and the second semiconductor chip 500 to the through-electrode 245.

The upper wiring insulating layer 240 may surround the upper wiring pattern 250. The upper wiring insulating layer 240 may be provided by stacking layers on one another in the vertical direction Z.

The upper wiring pattern 250 may be formed by stacking metals or alloys of the metals on a seed layer including copper, titanium, titanium nitride, or titanium tungsten.

The upper wiring insulating layer 240 may include, for example, a photo imageable dielectric (PID) or photosensitive polyimide (PSPI).

The upper wiring pattern 250 may include an upper wiring line pattern 253 and an upper wiring via pattern 251. The upper wiring line pattern 253 may have a shape that extends in a horizontal direction along at least one of the upper surface and the lower surface of each of the plurality of upper wiring insulating layers 240 stacked in the vertical direction Z. The upper wiring via pattern 251 may have a shape that extends through the upper wiring insulating layer 240 in the vertical direction Z. The upper wiring via pattern 251 may electrically connect upper wiring line patterns 253 at different vertical levels to each other. In some implementations, at least some of the upper wiring line patterns 253 may be formed integrally with some of the upper wiring via patterns 251.

A bonding pad 265 may be disposed on the upper wiring layer 243. The bonding pad 265 may be provided in plurality. At least some of the plurality of bonding pads 265 may be electrically connected to the upper wiring pattern 250. A bonding insulating layer 260 may cover side surfaces of the bonding pad 265 on the upper wiring layer 243.

The footprint of the bonding insulating layer 260 may have substantially the same footprint as the upper wiring layer 243. The bonding insulating layer 260 may not overlap the groove G of the body 220 in the vertical direction Z.

The EIC 300, the first semiconductor chip 400, and the second semiconductor chip 500 may be disposed on the bonding pad 265 and the bonding insulating layer 260. The EIC 300, the first semiconductor chip 400, and the second semiconductor chip 500 may be spaced apart from each other in one or both of the horizontal directions X and Y.

In some implementations, the EIC 300 may overlap the PIC 231 in the vertical direction Z. The EIC 300 may be connected to the interposer substrate 200 by direct bonding via an EIC chip bonding pad 310 and an EIC chip bonding insulating layer 330 that surrounds side surfaces of the EIC chip bonding pad 310. The direct bonding may include dielectric-to-dielectric bonding, copper-to-copper bonding, and/or hybrid bonding in which both the dielectric-to-dielectric bonding and metal-to-metal bonding occur. The direct bonding may represent diffusion bonding, in which two interfaces containing the same material and facing each other are brought into contact with each other and heated so that metal atoms or dielectric materials in contact with each other are diffused to form a single body. The horizontal cross-section of the EIC chip bonding insulating layer 330 may have substantially the same area as the horizontal cross-section of the EIC 300. The horizontal cross-section of the EIC chip bonding pad 310 may be substantially the same as the horizontal cross-section of the bonding pad 265.

The first semiconductor chip 400 may be disposed on the interposer substrate 200 and spaced apart from the EIC 300 in the horizontal direction(s) X and/or Y with the second semiconductor chip 500 therebetween. The first semiconductor chip 400 may be directly bonded to the interposer substrate 200 via a first semiconductor chip bonding pad 410 and a first semiconductor chip bonding insulating layer 430. The horizontal cross-section of the first semiconductor chip bonding insulating layer 430 may have substantially the same area as the horizontal cross-section of the first semiconductor chip 400. The horizontal cross-section of the first semiconductor chip bonding pad 410 may have substantially the same area as the horizontal cross-section of the bonding pad 265.

In some implementations, the first semiconductor chip 400 may include a memory chip. The memory chip may include, for example, volatile memory chips, such as dynamic random-access memory (DRAM) and static random-access memory (SRAM), or non-volatile memory chips, such as phase-change random-access memory (PRAM), magnetoresistive random-access memory (MRAM), ferroelectric random-access memory (FeRAM), and resistive random-access memory (RRAM).

In some implementations, the memory chip may form high bandwidth memory (HBM) or a wire bonding memory package, in which a plurality of memory chips are stacked in the vertical direction Z.

The second semiconductor chip 500 may be disposed on the interposer substrate 200 and spaced apart from the EIC 300 and the first semiconductor chip 400 in the horizontal direction(s) X and/or Y. The second semiconductor chip 500 may be directly bonded to the interposer substrate 200 via a second semiconductor chip bonding pad 510 and a second semiconductor chip bonding insulating layer 530. The horizontal cross-section of the second semiconductor chip bonding insulating layer 530 may have substantially the same area as the horizontal cross-section of the second semiconductor chip 500. The horizontal cross-section of the second semiconductor chip bonding pad 510 may have substantially the same area as the horizontal cross-section of the bonding pad 265.

In some implementations, the second semiconductor chip 500 may include a logic chip. The logic chip may include, for example, microprocessors, such as a central processing unit (CPU), a graphics processing unit (GPU), and an application processor (AP), analog devices, or digital signal processors.

However, the first semiconductor chip 400 is not limited to a memory chip, and the second semiconductor chip 500 is not limited to a logic chip. In some implementations, the first semiconductor chip 400 and the second semiconductor chip 500 may each include a memory chip or a logic chip. For example, the first semiconductor chip 400 may include the logic chip, and the second semiconductor chip 500 may include the memory chip.

In some implementations, the upper surface of the bonding insulating layer 260 may be partially exposed upward in the vertical direction Z through the EIC chip bonding insulating layer 330, the first semiconductor chip bonding insulating layer 430, and the second semiconductor chip bonding insulating layer 530.

The optical fiber 600 may be in contact with the upper wiring layer 243 and the bonding insulating layer 260 in a lateral (horizontal) direction and may be in contact with the body 220 in the vertical direction Z and the first horizontal direction X. The optical fiber 600 may be coupled to the interposer substrate 200 via the groove G formed in the body 220. In some implementations, the optical fiber 600 may be in contact with the waveguide 235 in the lateral direction.

The optical fiber 600 may transmit an optical signal from a source outside the semiconductor package 10 to the waveguide 235 of the PIC 231. The optical fiber 600 may include a protrusion 610. The protrusion 610 may be coupled to the groove G located in the body 220 of the interposer substrate 200. A vertical cross-section of the groove G of the body 220 of the interposer substrate 200 may have substantially the same shape as A vertical cross-section of the protrusion 610 of the optical fiber 600. For example, the cross-section of the protrusion 610 in the X-Z plane may have substantially the same shape as the cross-section of the groove G in the X-Z plane, and the cross-section of the protrusion 610 in the Y-Z plane may have substantially the same shape as the cross-section of the groove G in the Y-Z plane.

The optical fiber 600 may include a plurality of bundles (fiber bundles). The plurality of bundles may be in contact with the EIC 300 in the lateral direction.

The lower wiring layer 190 may include the lower wiring pattern 193 and a lower wiring insulating layer 191. The lower wiring pattern 193 may be electrically connected to the through-electrode 245. Also, the lower wiring pattern 193 may be electrically connected to the bump structure 160. The bump structure 160 may include connection bumps, such as micro bumps. In some implementations, the bump structure 160 may be electrically connected to external connection devices, such as a package substrate or a motherboard. The bump structure 160 may include a pillar structure, a ball structure, or a solder layer.

In some implementations of the semiconductor package 10, because the PIC 231 is located inside the interposer substrate 200, only the EIC 300 is mounted on the interposer substrate 200. For example, a separate PIC chip may not be necessary or included. Therefore, a process of separately manufacturing a PIC chip and mounting the PIC chip on the interposer substrate 200 may be omitted.

Also, the optical fiber 600 may include the protrusion 610, and the groove G may be located in the upper surface of the body 220 of the interposer substrate 200. The protrusion 610 may be coupled to the groove G in the upper surface of the body 220 of the interposer substrate 200, and thus, the optical fiber 600 may be firmly coupled to the body 220 of the interposer substrate 200.

As the optical fiber 600 is firmly coupled to the body 220 of the interposer substrate 200, the movement of the optical fiber 600 may be restricted, thereby maintaining alignment between the optical fiber 600 and the EIC 300. Accordingly, the coupling reliability between the optical fiber 600 and the PIC 231 may be improved. For example, the signal transmission reliability of the optical fiber 600 may be improved.

In addition, because the EIC 300 is mounted directly on the interposer substrate 200, the heat management of the EIC 300 may be facilitated.

FIG. 3 is a cross-sectional view schematically showing an example of the semiconductor package 10 taken along line B1-B1' of FIG. 1, such that FIG. 3 illustrates a cross-section in the Y-Z plane. Hereinafter, repeated descriptions as those given with reference to FIGS. 1 and 2 are omitted, and the description focuses on the differences.

Referring to FIGS. 1 to 3, the semiconductor package 10 may include the interposer substrate 200, the optical fiber 600, the EIC 300, the first semiconductor chip 400, and the second semiconductor chip 500.

The interposer substrate 200 may include the body 220, the oxide layer 205, the through-electrode 245, the upper wiring layer 243, and the lower wiring layer 190. The groove G may be located in the upper surface of the body 220.

The optical fiber 600 may include the protrusion 610. The protrusion 610 may be coupled to the groove G of the body 220.

In some implementations, the vertical cross-section of the protrusion 610 may have a triangular shape. It may be understood that the vertical cross-section represents a cross-section in the Y-Z plane. In some implementations, the vertical cross-section of the protrusion 610 may have various triangular shapes, such as an isosceles triangle or an equilateral triangle. In some implementations, the triangle may have a shape in which the base of the triangle faces upward in the vertical direction Z (from the perspective shown in FIG. 3) and the hypotenuse of the triangle faces toward the inside of the body 220. The horizontal width of the protrusion 610 may change continuously.

The vertical cross-section of the groove G of the body 220 may have a triangular shape. It may be understood that the vertical cross-section represents a cross-section in the Y-Z plane. Also, the vertical cross-section of the groove G may be understood as the cross-section of an arbitrary material in the Y-Z plane when the groove G is completely filled with the arbitrary material. In some implementations, the vertical cross-section of the groove G may have various triangular shapes, such as an isosceles triangle or an equilateral triangle. In this case, the triangle may have a shape in which the base of the triangle faces upward in the vertical direction Z (from the perspective shown in FIG. 3) and the hypotenuse of the triangle faces the inside of the body 220.

The vertical cross-section of the groove G of the body 220 of the interposer substrate 200 may have substantially the same shape as the vertical cross-section of the protrusion 610 of the optical fiber 600.

In some implementations, the depth of the groove G may be in a range of about 20 nm to about 40 nm. In some implementations, the angle formed between the protrusion 610 and the upper surface of the body 220 may be in a range of about 120° to about 140°.The angle formed between the protrusion 610 and the upper surface of the body 220 may represent the angle formed between the vertical cross-section of the protrusion 610 and the vertical cross-section of the upper surface of the body 220. The angle formed between the protrusion 610 and the surface of the optical fiber 600 on which the protrusion 610 is formed may be in a range of about 120° to about 140°. The angle formed between the side surface of the groove G and the upper surface of the body 220 may be in a range of about 120° to about 140°.

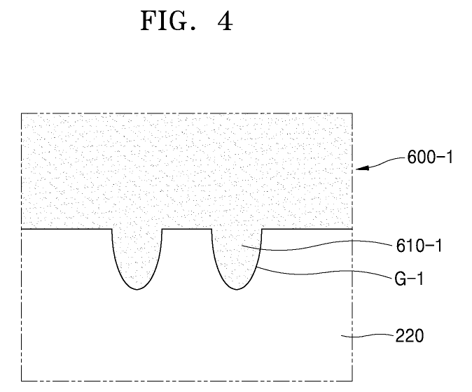

FIG. 4 is a cross-sectional view schematically showing an example of the semiconductor package 10 taken along line B1-B1' of FIG. 1, such that FIG. 4 illustrates a cross-section in the Y-Z plane. Hereinafter, repeated descriptions as those given with reference to FIGS. 1 to 3 are omitted, and the description focuses on the differences.

Referring to FIGS. 1, 2, and 4, the semiconductor package 10 may include the interposer substrate 200, an optical fiber 600-1, the EIC 300, the first semiconductor chip 400, and the second semiconductor chip 500.

The interposer substrate 200 may include the body 220, the oxide layer 205, the through-electrode 245, the upper wiring layer 243, and the lower wiring layer 190. A groove G-1 may be located in the upper surface of the body 220.

The optical fiber 600-1 may include a protrusion 610-1. The protrusion 610-1 may be coupled to the groove G-1 of the body 220.

In some implementations, the vertical cross-section of the protrusion 610-1 may have a semicircular or otherwise curved shape. It may be understood that the vertical cross-section represents a cross-section in the Y-Z plane. In some implementations, the vertical cross-section of the protrusion 610-1 may have a semicircular shape, a semi-elliptical shape, or the like. In some implementations, the geometric shape that forms the vertical cross-section of the protrusion 610-1 may include a curve. In this case, the curved portion may be at least partially in contact with the body 220. The horizontal width of the protrusion 610-1 may change continuously in the vertical direction.

The vertical cross-section of the groove G-1 of the body 220 may have a semicircular shape. It may be understood that the vertical cross-section represents a cross-section in the Y-Z plane. Also, the vertical cross-section of the groove G-1 may be understood as the cross-section of an arbitrary material in the Y-Z plane when the groove G-1 is completely filled with the arbitrary material. In some implementations, the vertical cross-section of the groove G-1 may have a semicircular shape, a semi-elliptical shape, or the like. In some implementations, the geometric shape that forms the vertical cross-section of the groove G-1 may include a curve. In this case, the curved portion may be at least partially in contact with the optical fiber 600-1.

The vertical cross-section of the groove G-1 of the body 220 of the interposer substrate 200 may have substantially the same shape as the vertical cross-section of the protrusion 610-1 of the optical fiber 600-1.

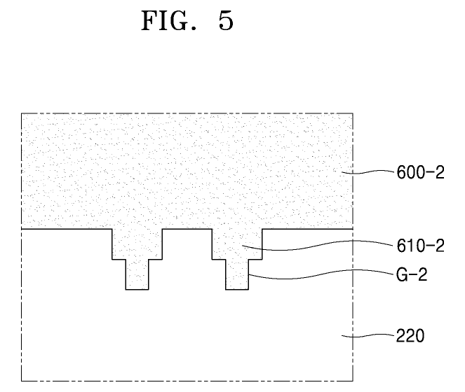

FIG. 5 is a cross-sectional view schematically showing an example of the semiconductor package 10 taken along line B1-B1' of FIG. 1, such that FIG. 5 illustrates a cross-section in the Y-Z plane. Hereinafter, repeated descriptions as those given with reference to FIGS. 1 to 4 are omitted, and the description focuses on the differences.

Referring to FIGS. 1, 2, and 5, the semiconductor package 10 may include the interposer substrate 200, an optical fiber 600-2, the EIC 300, the first semiconductor chip 400, and the second semiconductor chip 500.

The interposer substrate 200 may include the body 220, the oxide layer 205, the through-electrode 245, the upper wiring layer 243, and the lower wiring layer 190. A groove G-2 may be located in the upper surface of the body 220.

The optical fiber 600-2 may include a protrusion 610-2. The protrusion 610-2 may be coupled to the groove G-2 of the body 220.

In some implementations, the vertical cross-section of the protrusion 610-2 may have a stepped shape. It may be understood that the vertical cross-section represents a cross-section in the Y-Z plane. In some implementations, the vertical cross-section of the protrusion 610-2 may have a shape in which a rectangle having a relatively large horizontal width and a rectangle having a relatively small horizontal width are coupled to or adjacent to each other. In some implementations, the horizontal width of the protrusion 610-2 may decrease in a stepped shape as the vertical level decreases (from the perspective shown in FIG. 5). For example, as the vertical level decreases, the horizontal width of the protrusion 610-2 remains substantially constant to a certain level. However, when the level falls below the certain level, the horizontal width of the protrusion 610-2 may decrease. The horizontal width of the protrusion 610-2 may change discontinuously.

The vertical cross-section of the groove G-2 of the body 220 may have a stepped shape. It may be understood that the vertical cross-section represents a cross-section in the Y-Z plane. Also, the vertical cross-section of the groove G-2 may be understood as the cross-section of an arbitrary material in the Y-Z plane when the groove G-2 is completely filled with the arbitrary material. In some implementations, the vertical cross-section of the groove G-2 may have a shape in which a rectangle having a relatively large horizontal width and a rectangle having a relatively small horizontal width are coupled to or adjacent to each other. In some implementations, the horizontal width of the groove G-2 may decrease in a stepped shape as the vertical level decreases. For example, as the vertical level decreases (from the perspective shown in FIG. 5), the horizontal width of the groove G-2 remains substantially constant to a certain level. However, when the level falls below the certain level, the horizontal width of the groove G-2 may decrease. The horizontal width of the groove G-2 may change discontinuously. The vertical cross-section of the groove G-2 may have a first width that is substantially constant from the upper surface of the body 220 to the certain vertical level and a second width that is substantially constant from the certain vertical level to the lower surface of the groove G-2. Also, the first width of the groove G-2 may be greater than the second width of the groove G-2.

The vertical cross-section of the groove G-2 of the body 220 of the interposer substrate 200 may have substantially the same shape as the vertical cross-section of the protrusion 610-2 of the optical fiber 600-2.

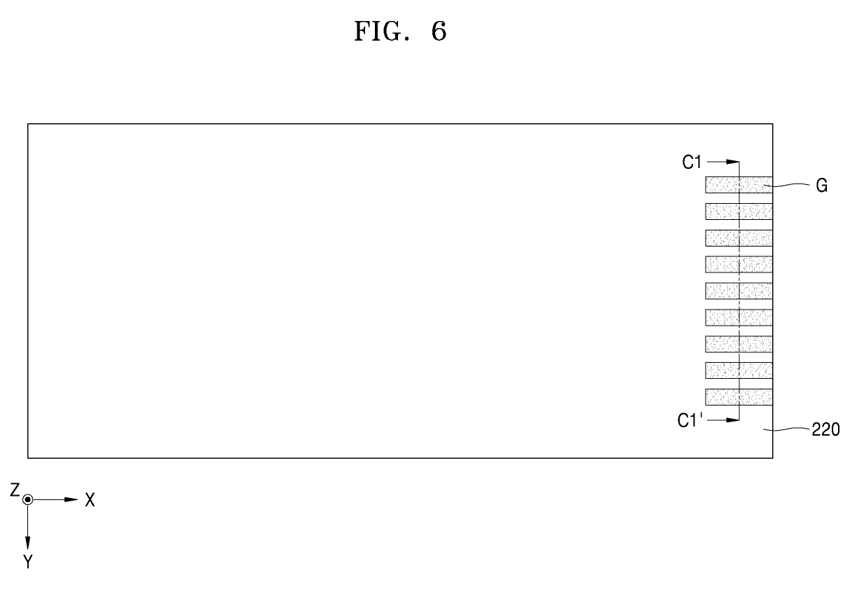

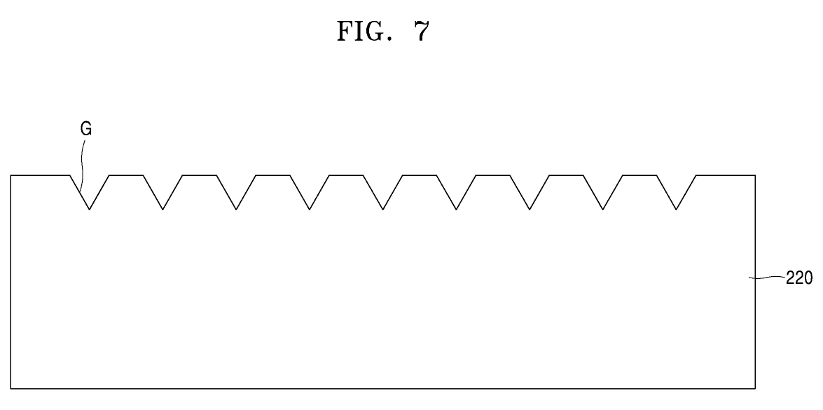

FIG. 6 is a schematic view showing an example of the upper surface of the body 220 of the semiconductor package 10 of FIG. 2. FIG. 7 is a cross-sectional view of the body 220 taken along line C1-C1' of FIG. 6. Hereinafter, repeated descriptions as those given with reference to FIGS. 1 to 5 are omitted, and the description focuses on the differences.

Referring to FIGS. 1, 2, 6, and 7, the groove G may be located in the upper surface of the body 220 of the interposer substrate 200. The optical fiber 600 may be disposed on the groove G in the upper surface of the body 220. The optical fiber 600 may overlap the groove G in the vertical direction Z.

The groove G may not overlap each of the upper wiring layer 243, the bonding insulating layer 260, and the EIC 300 in the vertical direction Z. In some implementations, the upper wiring layer 243 may completely cover the upper surface of the body 220 except for the groove G. The groove G may be provided in plurality. The plurality of grooves G may be spaced apart from each other in the second horizontal direction Y.

In some implementations, the groove G may have a rectangular shape when viewed from above in the vertical direction Z. For example, the cross-section of the groove G in the X-Y plane may have a rectangular shape. In some implementations, one side surface of the cross-section, e.g., the horizontal cross-section, of the groove G in the X-Y plane may be coplanar with one side surface of the body 220. For example, the side surface of the groove G in the first horizontal direction X may be coplanar with the side surface of the body 220 in the first horizontal direction X.

The protrusion 610 may have the same shape as the groove G. Accordingly, the horizontal cross-section of the protrusion 610 may have a rectangular shape. In some implementations, the cross-section of the groove G in the Y-Z plane may have the shapes described with reference to FIGS. 3 to 5. In FIG. 7, for convenience of illustration, the cross-section of the groove G in the Y-Z plane is shown as a triangular shape, but the cross-sectional shape of the groove G in the Y-Z plane is not limited thereto.

The plurality of grooves G may be spaced apart from each other in the second horizontal direction Y. Each of the plurality of grooves G may extend in the first horizontal direction X as shown in FIG. 6.

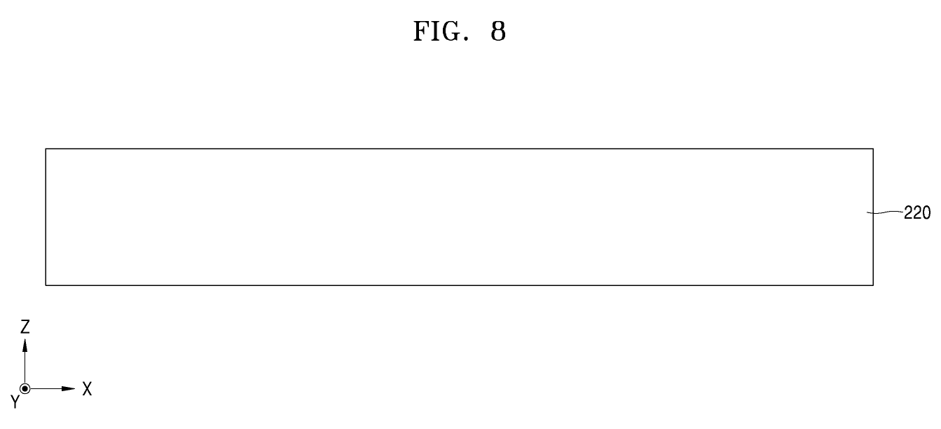

FIGS. 8 to 18 are cross-sectional views illustrating an example of a method of manufacturing the semiconductor package 10 of FIG. 2. Hereinafter, repeated descriptions as those given with reference to FIGS. 1 to 7 are omitted, and the description focuses on the differences.

Referring to FIG. 8, the body 220 constituting the interposer substrate 200 (see FIG. 2) is prepared. The body 220 may include silicon. The body 220 may also be understood as a silicon wafer, a silicon substrate, or a silicon body.

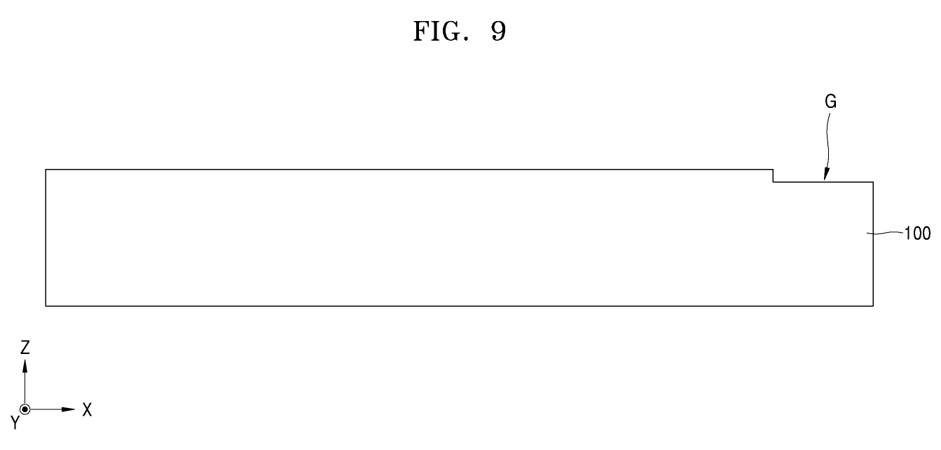

Referring to FIG. 9, the groove G is formed in the edge of the body 220. The groove G may be formed by an etching process. In some implementations, the groove G may be provided in plurality and spaced apart from each other in the second horizontal direction Y. The vertical cross-section and the horizontal cross-section of the groove G may each have the same shape as described above with reference to FIGS. 1 to 7.

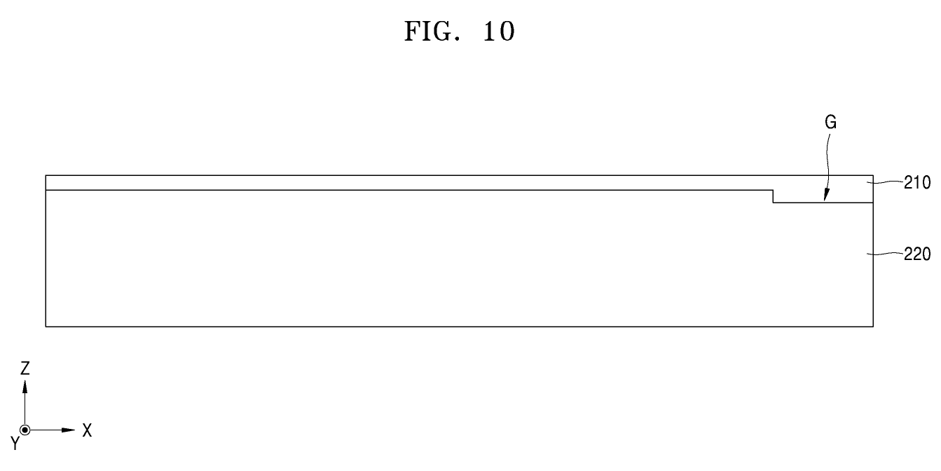

Referring to FIG. 10, the first oxide layer 210 is formed to cover the upper surface of the body 220. The first oxide layer 210 may cover not only the upper surface of the body 220 but also the groove G. The first oxide layer 210 may be, for example, a BOX layer. The first oxide layer 210 may be formed by an oxidation process. The oxidation process may include chemical vapor deposition, physical vapor deposition, etc.

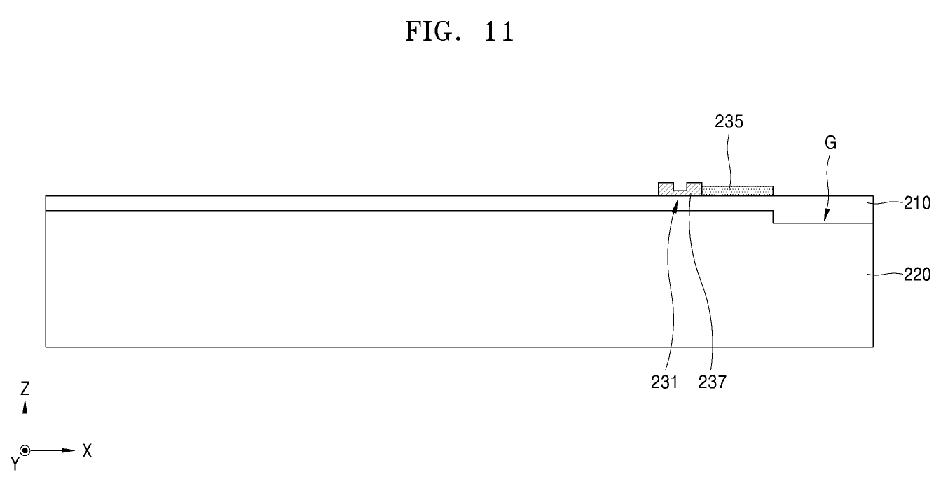

Referring to FIG. 11, the PIC 231 is formed on the first oxide layer 210. The PIC 231 may include the waveguide 235 and the optical component 237. The PIC 231 may be located close to the groove G.

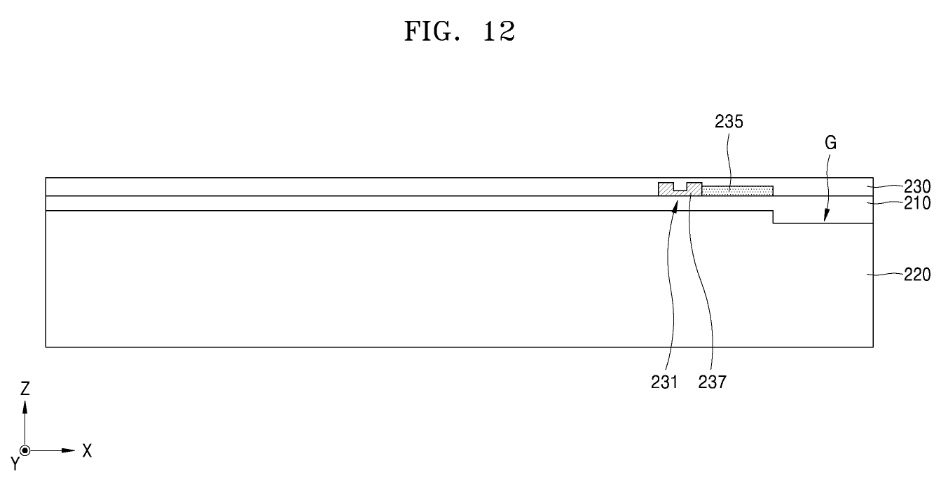

Referring to FIG. 12, the second oxide layer 230 covering the PIC 231 is formed on the first oxide layer 210. The second oxide layer 230 may be formed by the same process as the first oxide layer 210. The second oxide layer 230 may cover the PIC 231. The waveguide 235 and the optical component 237 may be covered by the second oxide layer 230.

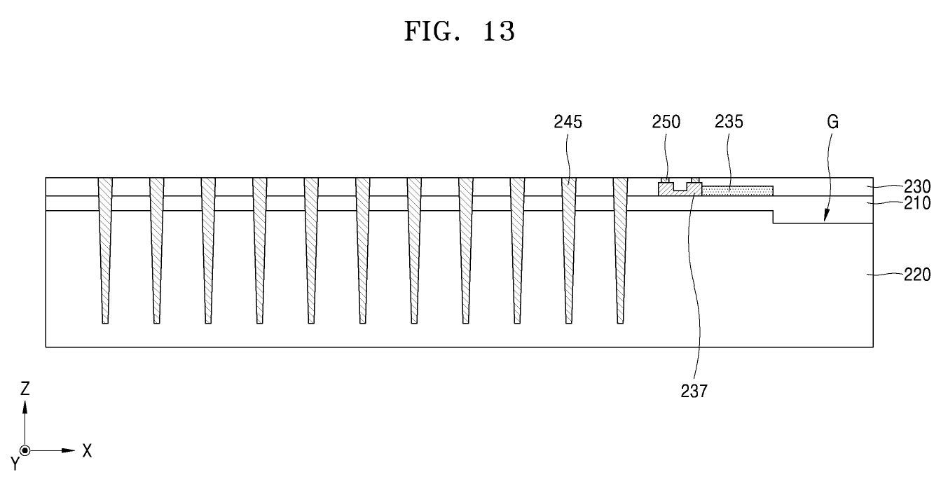

Referring to FIG. 13, the through-electrode 245 is formed so as to pass through the second oxide layer 230, the first oxide layer 210, and the body 220 in the vertical Z direction. The through-electrode 245 may completely pass through the second oxide layer 230 and the first oxide layer 210 and partially pass through the body 220 in the vertical direction Z. The through-electrode 245 may not be in contact with the lower surface of the body 220. Accordingly, the through-electrode 245 may not be exposed at the lower surface of the body 220.

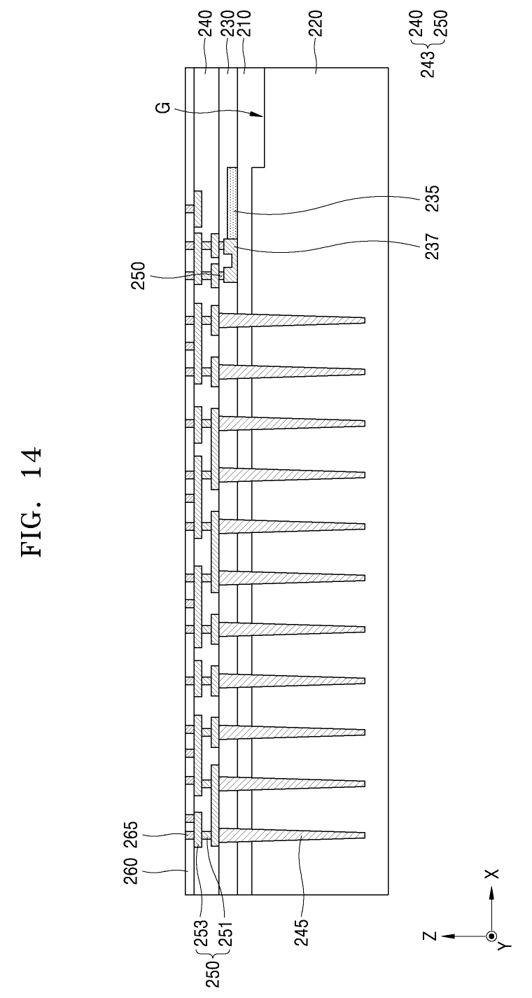

Referring to FIG. 14, the upper wiring layer 243 including the upper wiring pattern 250 and the upper wiring insulating layer 240 is formed on the second oxide layer 230, and the bonding pad 265 and the bonding insulating layer 260 are formed on the upper wiring layer 243.

In this case, the upper wiring pattern 250 in the upper wiring layer 243 and the bonding pad 265 may not overlap the groove G in the vertical direction Z.

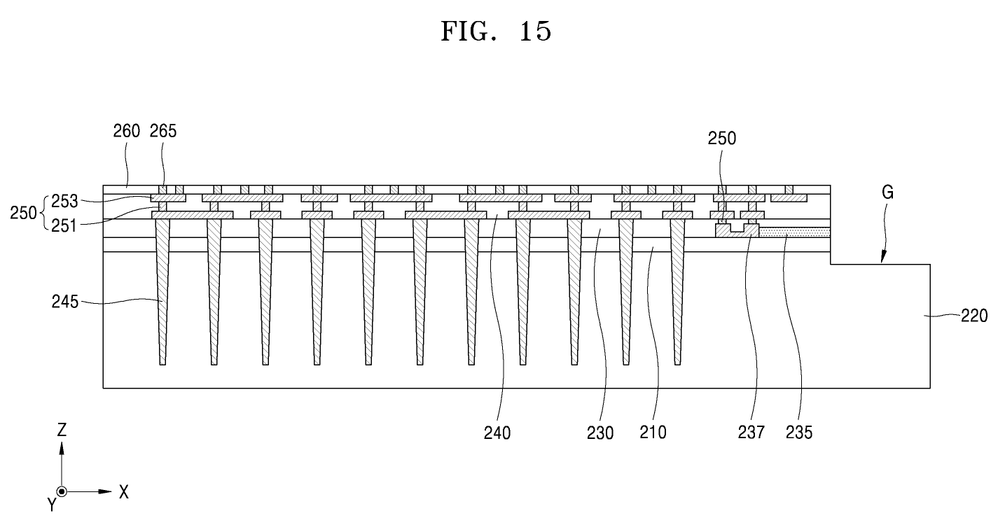

Referring to FIG. 15, the bonding insulating layer 260 and the upper wiring layer 243 are partially etched from the upper surface to expose the groove G upward in the vertical direction Z. As the bonding insulating layer 260 and the upper wiring layer 243 are partially etched, the groove G may be exposed upward in the vertical direction Z.

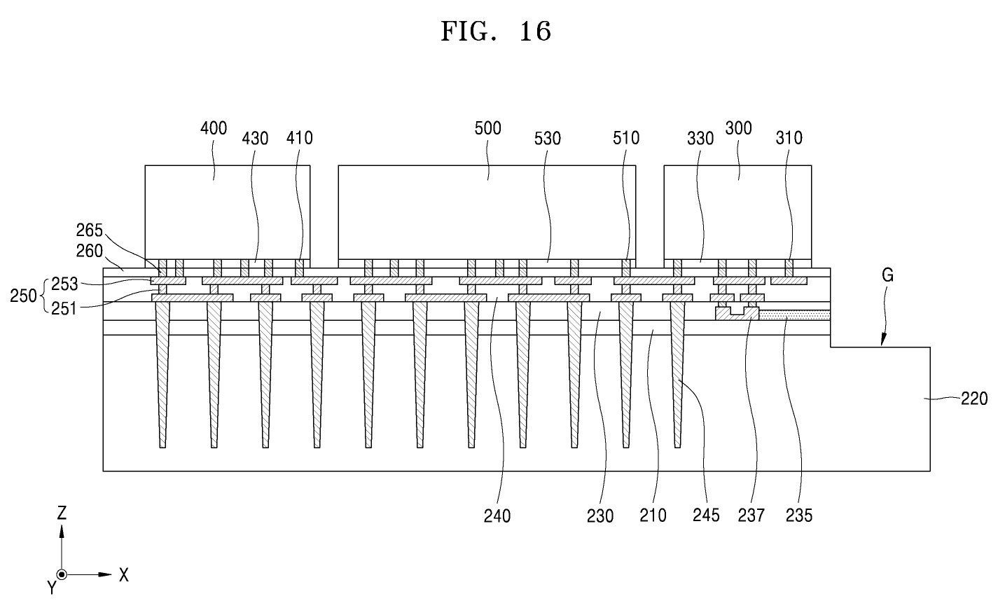

Referring to FIG. 16, the EIC 300, the first semiconductor chip 400, and the second semiconductor chip 500 are bonded to the upper wiring layer 243 by direct bonding. The direct bonding may include hybrid copper bonding. The bonding insulating layer 260 and the bonding pads 265 may be shared between the upper wiring layer 243 and the EIC 300, between the upper wiring layer 243 and the first semiconductor chip 400, and between the upper wiring layer 243 and the second semiconductor chip 500. The EIC chip bonding insulating layer 330 and the EIC chip bonding pad 310 may be further provided between the upper wiring layer 243 and the EIC 300. The first semiconductor chip bonding insulating layer 430 and the first semiconductor chip bonding pad 410 may be further provided between the upper wiring layer 243 and the first semiconductor chip 400. The second semiconductor chip bonding insulating layer 530 and the second semiconductor chip bonding pad 510 may be further provided between the upper wiring layer 243 and the second semiconductor chip 500.

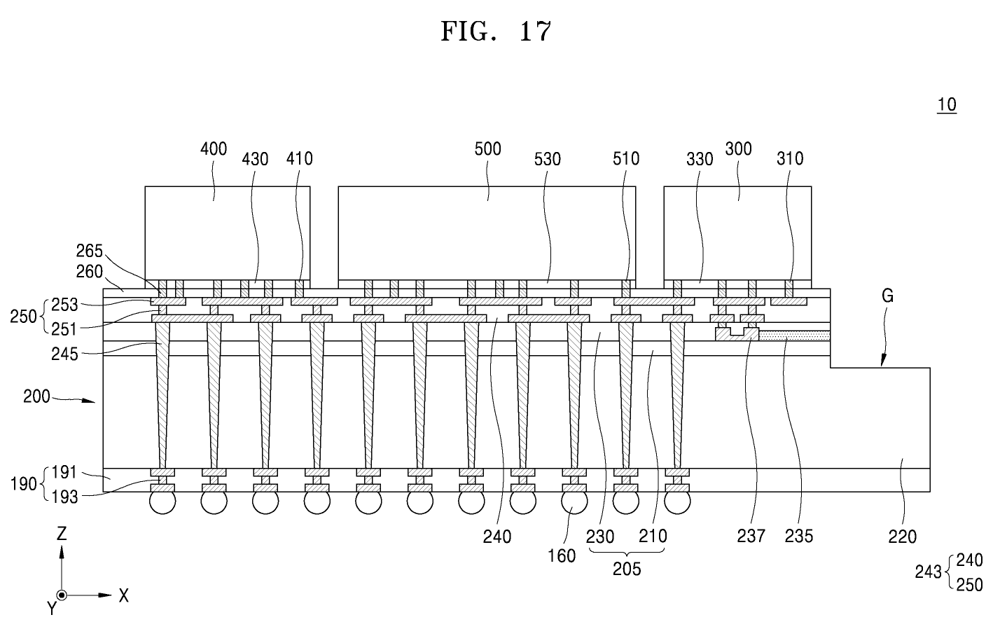

Referring to FIG. 17, the body 220 may be etched from the lower surface of the body 220 to a certain position by a grinding process or a chemical mechanical polishing process, thereby exposing the through-electrode 245 downward in the vertical direction Z. Subsequently, the lower wiring layer 190 and the bump structure 160 are formed.

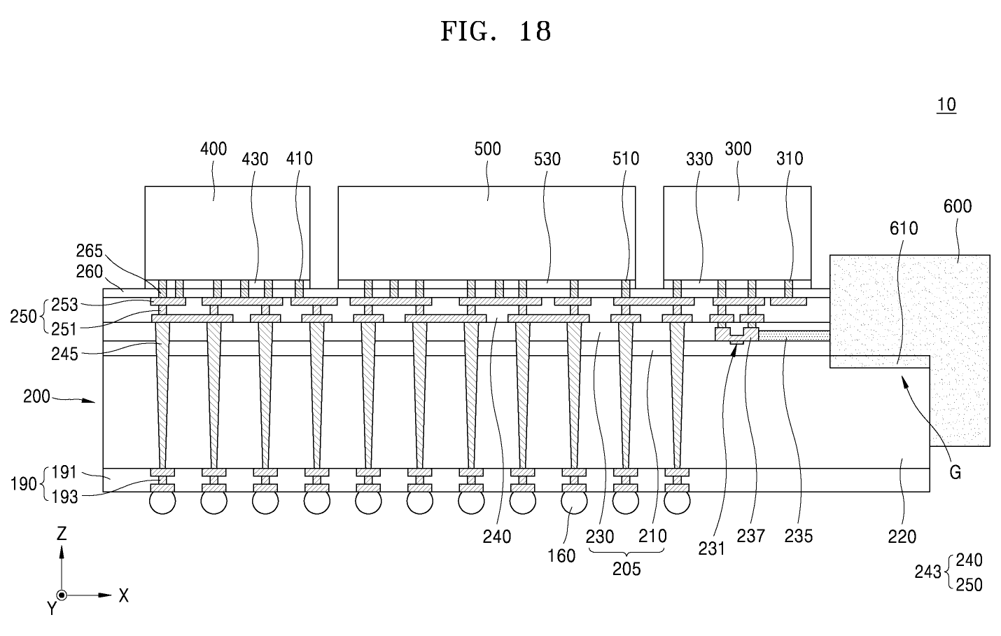

Referring to FIG. 18, the protrusion 610 of the optical fiber 600 is coupled to the groove G of the body 220, and thus, the semiconductor package 10 is completely manufactured.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While certain examples have been particularly shown and described, it will be understood that various changes in form and details may be made therein without departing from the spirit and scope of this disclosure.

What is claimed is:

1. A semiconductor package comprising:
a body having an upper surface and a lower surface, wherein the body comprises a groove extending downward from the upper surface of the body in a vertical direction;
an oxide layer on the body;
a waveguide and an optical component connected to the waveguide, wherein the waveguide and the optical component are in the oxide layer, and wherein the waveguide and the optical component are spaced apart from the groove of the body in a horizontal direction;
an upper wiring layer on the oxide layer, wherein the upper wiring layer comprises an upper wiring pattern and an upper wiring insulating layer surrounding the upper wiring pattern;
a through-electrode electrically connected to the upper wiring pattern, wherein the through-electrode extends in the body and the oxide layer in the vertical direction;
a bonding pad on the upper wiring layer;
a bonding insulating layer surrounding a side surface of the bonding pad;
an electronic integrated circuit (EIC) chip on the bonding pad and the bonding insulating layer; and
an optical fiber mounted on the groove, wherein the optical fiber comprises a protrusion extending into the groove, and wherein the optical fiber is in contact with the upper wiring layer in the horizontal direction.

2. The semiconductor package of claim 1, wherein a vertical cross-section of the groove has a triangular shape.

3. The semiconductor package of claim 1, wherein a depth of the groove is in a range from 20 nm to 40 nm, and
wherein an angle between a side surface of the groove and the upper surface of the body is in a range from 120° to 140°.

4. The semiconductor package of claim 1, wherein, in a vertical cross-section of the groove, a horizontal width of the groove decreases downward in the vertical direction, and
wherein the vertical cross-section of the groove comprises a curve.

5. The semiconductor package of claim 1, wherein a vertical cross-section of the groove comprises:
a first portion having a first horizontal width, wherein the first horizontal width is substantially constant from the upper surface of the body to a first vertical level, and
a second portion having a second horizontal width, wherein the second horizontal width is substantially constant from the first vertical level to a lower surface of the groove, and
wherein the first horizontal width is greater than the second horizontal width.

6. The semiconductor package of claim 1, wherein the groove is spaced apart from the upper wiring pattern and the bonding pad in the horizontal direction.

7. The semiconductor package of claim 1, wherein the EIC chip comprises, on a lower surface of the EIC chip, an EIC chip bonding pad and an EIC chip bonding insulating layer surrounding a side surface of the EIC chip bonding pad,
wherein the EIC chip bonding pad is in contact with the bonding pad, and
wherein the EIC chip bonding insulating layer is in contact with the bonding insulating layer.

8. The semiconductor package of claim 1, wherein the oxide layer comprises a first oxide layer and a second oxide layer, and wherein the waveguide and the optical component are disposed on an upper surface of the first oxide layer.

9. The semiconductor package of claim 1, wherein a horizontal cross-section of the groove has a quadrangular shape.

10. The semiconductor package of claim 9, wherein a side surface of the horizontal cross-section of the groove is coplanar with a side surface of the body.

11. The semiconductor package of claim 1, wherein the body comprises a plurality of grooves extending downward from the upper surface of the body in the vertical direction, and
wherein the plurality of grooves are spaced apart from each other in a second horizontal direction perpendicular to the horizontal direction.

12. The semiconductor package of claim 11, wherein each groove of the plurality of grooves extends in the horizontal direction.

13. A semiconductor package comprising:
an interposer substrate;
an electronic integrated circuit (EIC) chip on the interposer substrate;
a first semiconductor chip on the interposer substrate and spaced horizontally apart from the EIC chip;
a second semiconductor chip on the interposer substrate and horizontally between the first semiconductor chip and the EIC chip; and
an optical fiber comprising a protrusion, wherein the optical fiber is in contact with the interposer substrate in a horizontal direction,
wherein the interposer substrate comprises:
a body having an upper surface and a lower surface, wherein the body comprises a groove extending downward from the upper surface of the body in a vertical direction,
an oxide layer on the body,
a waveguide and an optical component connected to the waveguide, wherein the waveguide and the optical component are in the oxide layer, and wherein the waveguide and the optical component are spaced apart from the groove of the body in a horizontal direction,
an upper wiring layer disposed on the oxide layer, wherein the upper wiring layer comprises an upper wiring pattern and an upper wiring insulating layer surrounding the upper wiring pattern,
a bonding pad on the upper wiring insulating layer,
a bonding insulating layer surrounding a side surface of the bonding pad, and
a through-electrode electrically connected to the upper wiring pattern, wherein the through-electrode extends in the body and the oxide layer in the vertical direction,
wherein the EIC chip comprises, on a lower surface of the EIC chip, an EIC chip bonding pad and an EIC chip bonding insulating layer surrounding a side surface of the EIC chip bonding pad,
wherein the first semiconductor chip comprises, on a lower surface of the first semiconductor chip, a first semiconductor chip bonding pad and a first semiconductor chip bonding insulating layer,
wherein the second semiconductor chip comprises, on a lower surface of the second semiconductor chip, a second semiconductor chip bonding pad and a second semiconductor chip bonding insulating layer,
wherein the EIC chip bonding pad, the first semiconductor chip bonding pad, and the second semiconductor chip bonding pad are each in contact with the bonding pad in the vertical direction, and
wherein the bonding insulating layer is exposed upward in the vertical direction past the EIC chip bonding insulating layer, the first semiconductor chip bonding insulating layer, and the second semiconductor chip bonding insulating layer.

14. The semiconductor package of claim 13, wherein a vertical cross-section of the groove has a triangular shape.

15. The semiconductor package of claim 13, wherein a horizontal cross-section of the groove has a quadrangular shape.

16. The semiconductor package of claim 13, wherein the body comprises a plurality of grooves extending downward from the upper surface of the body in the vertical direction,
wherein the plurality of grooves are spaced apart from each other in a second horizontal direction perpendicular to the horizontal direction, and
wherein each groove of the plurality of grooves extends in the horizontal direction.

17. The semiconductor package of claim 13, wherein the first semiconductor chip comprises a memory chip, and the second semiconductor chip comprises a logic chip.

18. A semiconductor package comprising:
an interposer substrate comprising:
a body having an upper surface and a lower surface, wherein the body comprises a groove extending downward from the upper surface of the body in a vertical direction,
an oxide layer on the body,
a waveguide and an optical component connected to the waveguide, wherein the waveguide and the optical component are in the oxide layer, and wherein the waveguide and the optical component are spaced apart from the groove of the body in a horizontal direction,
an upper wiring layer on the oxide layer, wherein the upper wiring layer comprises an upper wiring pattern and an upper wiring insulating layer surrounding the upper wiring pattern,
a bonding pad,
a bonding insulating layer, and
a through-electrode electrically connected to the upper wiring pattern, wherein the through-electrode passes through the body and the oxide layer in the vertical direction;
an electronic integrated circuit (EIC) chip on the interposer substrate and comprising, on a lower surface of the EIC chip, an EIC chip bonding pad and an EIC chip bonding insulating layer;
a first semiconductor chip on the interposer substrate, spaced horizontally apart from the EIC chip, and comprising, on a lower surface of the first semiconductor chip, a first semiconductor chip bonding pad and a first semiconductor chip bonding insulating layer;
a second semiconductor chip on the interposer substrate, located horizontally between the first semiconductor chip and the EIC chip, and comprising, on a lower surface of the second semiconductor chip, a second semiconductor chip bonding pad and a second semiconductor chip bonding insulating layer; and
an optical fiber comprising a protrusion, wherein the optical fiber is in contact with the interposer substrate in the horizontal direction,
wherein the EIC chip bonding pad, the first semiconductor chip bonding pad, and the second semiconductor chip bonding pad are each in contact with the bonding pad in the vertical direction,
wherein the bonding insulating layer is exposed upward in the vertical direction past the EIC chip bonding insulating layer, the first semiconductor chip bonding insulating layer, and the second semiconductor chip bonding insulating layer,
wherein the oxide layer comprises a first oxide layer and a second oxide layer,
wherein the waveguide and the optical component are on an upper surface of the first oxide layer,
wherein the groove is spaced apart from the upper wiring pattern and the bonding pad in the horizontal direction, and
wherein a depth of the groove is in a range from 20 nm to 40 nm.

19. The semiconductor package of claim 18, wherein, in a vertical cross-section of the groove, a horizontal width of the groove decreases downward in the vertical direction, and
wherein the vertical cross-section of the groove comprises a curve.

20. The semiconductor package of claim 18, wherein a vertical cross-section of the groove comprises:
a first portion having a first horizontal width, wherein the first horizontal width is substantially constant from the upper surface of the body to a first vertical level, and
a second portion having a second horizontal width, wherein the second horizontal width is substantially constant from the first vertical level to a lower surface of the groove, and
wherein the first horizontal width is greater than the second horizontal width.
